(19) United States
(12) Patent Application Publication
(10) Pub. No.: US 2002/0084453 A1
(43) Pub. Date: Jul. 4, 2002

(54) Hybrid oxide heterostructures and devices

(76) Inventor: Ivan Bozovic, Palo Alto, CA (US)

Correspondence Address: PERKINS COIE LLP, P.O. BOX 2168, MENLO PARK, CA, 94026, US

(21) Appl. No.: 09/965,063

(22) Filed: Sep. 27, 2001

Related U.S. Application Data
(60) Provisional application No. 60/236,041, filed on Sep. 27, 2000.

(51) Int. Cl. H01L 29/06; H01L 39/22; G11C 11/14

(52) U.S. Cl. 257/35; 257/43; 257/33; 257/34; 365/171; 365/173

(57) ABSTRACT

A hybrid oxide heterostructure device is disclosed. The device includes a substrate, and formed monolithically on the substrate, by atomic layer-by-layer molecular-beam epitaxy, successive metal oxide layers forming a high-temperature superconducting (HTS) structure and a multi-layer magnetic memory/storage structure. The HTS structure includes one or more HTS metal oxide layers formed on the substrate, and electrical contacts formed on the one or more HTS layers. The magnetic-memory structure includes one or more metal oxide magnetic layers formed monolithically on, below, or between the layer(s) of the HTS device, and having electrical contacts formed on one or more of the magnetic layers. Application of current or voltage to an HTS structure, under conditions effective to establish a superconducting current in the HTS structure, is effective to alter read or write characteristics of the memory-storage structure.

### BACKGROUND OF THE INVENTION

### Josephson Junctions

Tri-layer Josephson junctions (JJs) have been made with high-temperature superconductors (HTS) for a decade. They are sometimes also called sandwich junctions, or planar junctions. An example is shown schematically in FIG. 1. A way to fabricate such a junction is to deposit on a suitable substrate a tri-layer thin film, consisting of the bottom HTS electrode layer, an ultrathin (0.5 to 5 nm thick) barrier layer, and a top HTS electrode layer. After deposition, the film is etched, e.g., by ion milling, to form a mesa structure. Subsequently, some metallic contact pads may be added at the top of the mesa and at the bottom electrode, as shown in FIG. 1. If the barrier is insulating, one gets an SIS (superconductor-insulator-superconductor) junction; if the middle layer is metallic, this provides an SNS (superconductor-normal metal-superconductor) junction.

As an example, some typical materials choices would be:

For the substrate: SrTiO₃, LaAlO₃, LaSrAlO₄, and many others.

For the HTS electrodes: YBa₂Cu₃O₇ (Dy, Sm, Nd or other rare-earth metals are sometimes used instead of Y), La_{1.85}Sr_{0.15}CuO₄, or Bi₂Sr₂CaCu₂O₈.

For the insulating barrier: CaTiO₃, SrTiO₃, DyTiO₃, and many other compounds.

For the normal metal layer: Ca-doped or Co-doped YBa₂Cu₃O₇, Bi₂Sr₂CuO₆, Bi₂Sr₂Ca4Cu₂O₅, and many others.

For metallic electrical contacts: gold, silver, etc.

### Magnetic Tunnel Junction

Magnetically stored random access memory (MRAM) uses magneto-resistance (MR) to read the stored data. There are various configurations of MRAM devices, the most common of which is the magnetic tunnel junction (MTJ), shown in FIG. 2.

The device is comprised of a ‘sandwich’ of two ferromagnetic (FM) layers separated by an extremely thin insulating layer, which acts as a tunneling barrier. The current can be passed either perpendicular or parallel to the layers of the MTJ sandwich, but in the later case one needs two (or more) separate contacts to the top ferromagnetic layer. The perpendicular structure is preferred in MRAM devices, because it allows for higher areal densities.

In either case, the resistance of the MTJ sandwich depends on the magnetic arrangement of the magnetic moments of the two ferromagnetic layers. Typically, the resistance of the MTJ is lowest when these moments are aligned parallel to one another, as shown in FIG. 2a, and is highest when they are anti-parallel, as in FIG. 2b. This has been referred to as Tunneling Magneto-Resistance (TMR) effect. Frequently, the magnetization vector of one of the FM electrodes is anchored in a fixed orientation, e.g., by coupling to a neighboring strong anti-ferromagnet (AFM) layer. The other FM electrode is ‘free’ and it can be switched by an external magnetic field. The orientation of the magnetic moment of the latter (‘free’) electrode determines the memory state of the MTJ device.

### MRAMs

The general features of MRAM devices are: non-volatility, fast writing (˜5 nsec), low writing energy, write cycling without degradation (>10¹⁵ cycles), and non-destructive read out, unlike in ferroelectric (FE) memory.

The majority of the MRAM devices currently under development employ magnetic metals, similar to those used in GMR (Giant Magneto-Resistance) heads, i.e., cobalt, permalloy, etc. Using another class of materials, namely perovskite oxides such as (La—Ca)MnO₃, a much larger magneto-resistance effect has been found; it has been called Colossal Magnetic Resistance (CMR).

The larger magneto-resistance of an oxide MRAM should give several important advantages over metal-MRAM. Since the read access frequency is proportional to the square of the magneto-resistance signal, great improvements in read access times can be expected for MRAM devices incorporating oxide (CMR) materials. In addition, the larger signals of Oxide MRAM devices should permit simpler circuitry and hence higher density of devices.

The present application describers the construction and operation of novel that oxide heterostructures that can be monolithically integrated with, for example, HTS-based devices including HTS sandwich JJs, and other oxide devices. These hybrid devices provide novel and superior functionality.

### SUMMARY OF THE INVENTION

The invention includes a hybrid oxide heterostructure device that has a substrate, and formed monolithically on the substrate, successive metal oxide layers forming a high-temperature superconducting (HTS) structure and a multi-layer magnetic memory-storage structure. The HTS structure includes one or more HTS metal oxide layers formed on the substrate, and electrical contacts formed on the one or more HIS layers. The magnetic-memory structure includes one or more metal oxide magnetic layers formed monolithically with the HTS device, and having electrical contacts formed on one or more of the magnetic layers. The layer(s) of the memory-storage structure may be disposed below, on or between the layer(s) of the HTS structure. Application of current or voltage to an HTS structure, under conditions effective to establish a superconducting current in the HTS structure, is effective to alter read or write characteristics of the memory-storage structure.

The successive HTS and magnetic layers are preferably formed by atomic layer-by-layer molecular-beam epitaxy.

In one embodiment, the HTS structure has a single HTS layer and the memory-storage structure includes a metal oxide ferroelectric (FE) memory layer formed on the HTS layer. The HTS-structure electrical contacts are formed on opposite sides of the HTS layer, and the magnetic-storage structure electrical contacts are formed on the FE layer. Exemplary metal oxide layers in this embodiment are, for the HTS layer, La_{1.85}Sr_{0.15}CuO₄, DyBa₂Cu₃O₇, or Bi₂Sr₂CaCu₂O₈; and for the FE layer, (Ba,Sr)TiO₃, PbTiO₃, (Pb,La)(Zr,Ti)O₃, or Bi₃Ti₄O₁₀.

In another embodiment, the HTS structure has a single HTS layer and the memory-storage structure includes a metal oxide colossal magnetic resistance (CMR) layer formed on the HTS layer. The HTS-structure electrical contacts are formed on opposite sides of the HTS layer, and the magnetic/storage-structure electrical contacts are formed on the CMR layer. Exemplary metal oxide layers in this embodiment are, for the HTS layer, La_{1.85}Sr_{0.15}CuO₄, DyBa₂Cu₃O₇, or Bi₂Sr₂CaCu₂O₈; and for the CMR layer, La_{0.66}Sr_{0.34}MnO₄, La_{0.66}Ca_{0.34}MnO₄La_{0.66}Ba_{0.34}MnO₄. A combined HTS/FE/CMR heterostructure device is also contemplated.

In another embodiment, the HTS structure has a single HTS layer and the memory-storage structure includes a magnetic tunnel junction (MTJ) structure composed of a first ferromagnetic (FM) formed on the HTS layer, an insulating layer formed on the first FM layer, a second FM layer formed on the insulating layer, and a anti-ferromagnetic (AFM) layer formed on the second FM layer. The HTS-structure electrical contacts are formed on opposite sides of the HTS layer, and the magnetic-storage-structure electrical contacts are formed on the AFM layer. Exemplary metal oxide layers in this embodiment are, for the HTS layer, La_{1.85}Sr_{0.15}CuO₄, DyBa₂Cu₃O₇, or Bi₂Sr₂CaCu₂O₈; and for the FM layers, La_{0.66}Sr_{0.34}MnO₄, La_{0.66}Ca_{0.34}MnO₄, or La_{0.66}Ba_{0.34}MnO₄. The device may be constructed for in-plane or out-of-plane read-out current.

In another embodiment, the HTS structure is Josephson Junction (JJ) having a first HTS layer formed on the substrate, an insulating-barrier layer formed on the first HTS layer, and a second HTS layer formed on the insulating-barrier layer. The memory-storage structure includes a MTJ structure composed of a first ferromagnetic (FM) formed on the HTS layer, an insulating layer formed on the first FM layer, a second FM layer formed on the insulating layer, and a anti-ferromagnetic (AFM) layer formed on the second FM layer. The HTS-structure electrical contacts are formed on opposite sides of the HTS layer, and the magnetic/storage-structure electrical contacts are formed on the AFM layer. Exemplary metal oxides layers in this embodiment are, for the HTS layer, La_{1.85}Sr_{0.15}CuO₄, DyBa₂Cu₃O₇, or Bi₂Sr₂CaCu₂O₈; and for the FM layer La_{0.66}Sr_{0.34}MnO₄, La_{0.66}Ca_{0.34}MnO₄, and La_{0.66}Ba_{0.34}MnO₄.

These and other objects and features of the invention will become more fully apparent when the following detailed description of the invention is read in conjunction with the accompanying drawings.

### BRIEF DESCRIPTION OF THE DRAWINGS

FIG. 1 illustrates an HTS Josephson junction known in the prior art;

FIGS. 2A and 2B illustrate a magnetic tunnel junction (MTJ) device known in the prior art, shown in open (FIG. 2A) and closed (FIG. 2B) states;

FIG. 3 illustrates a CMR/FE/HTS heterostructure device formed in accordance with one embodiment of the invention;

FIGS. 4A and 4B illustrate an MTJ/HTS heterostructure device formed in accordance with another embodiment of the invention, designed for out-of-plane read out current, shown in open (FIG. 4A), and closed (FIG. 4B) states;

FIG. 4C illustrates a configuration for writing to the MTJ/HTS device of FIGS. 4A and 4B;

FIGS. 5A and 5B illustrate an MTJ/HTS heterostructure device formed in accordance with another embodiment of the invention, designed for in-plane read out current, shown in open (FIG. 5A), and closed (FIG. 5B) states; and

FIG. 6 illustrates an MTJ/JJ heterostructure device formed in accordance with yet another embodiment of the invention.

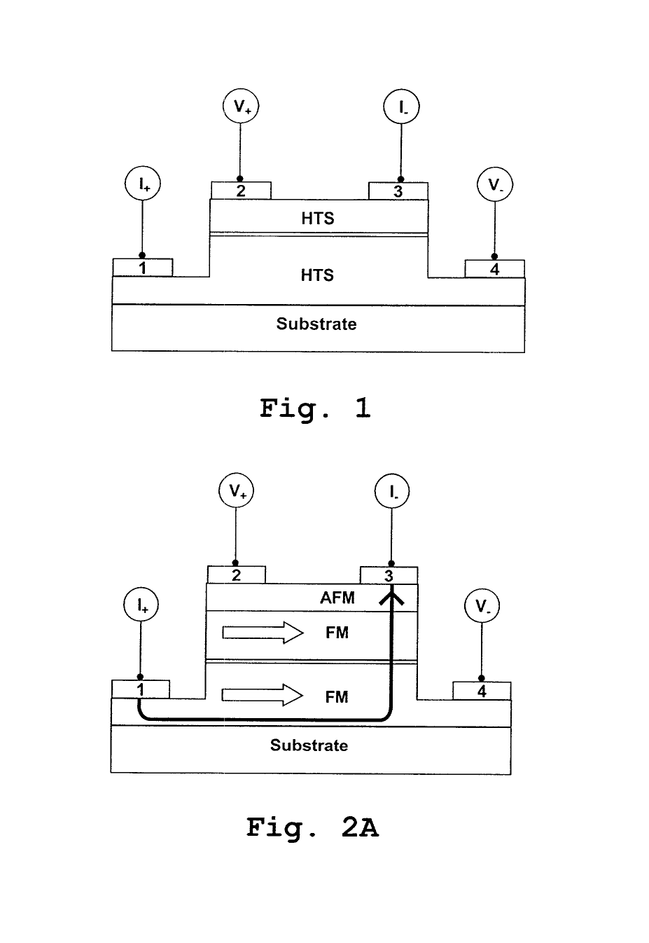

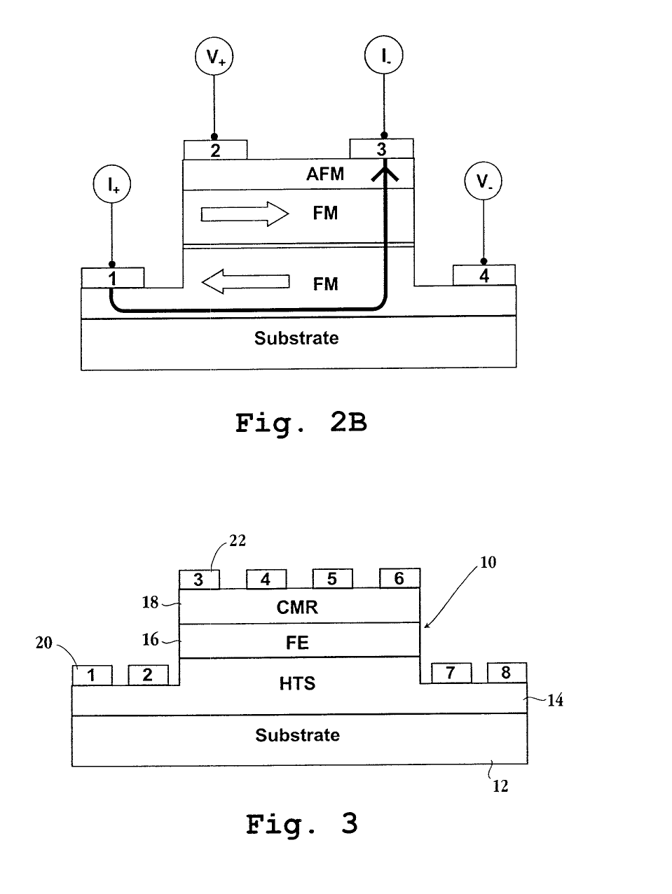

### DETAILED DESCRIPTION OF THE INVENTION

### A. Methods of Forming the Heterostructures

The heterostructures may be constructed by known substrate fabrication and layer-deposition methods, including methods described in several of the references cited above, which are incorporated herein by reference. These methods are also discussed in co-owned PCT application US/99/26129 for Combinatorial Molecular-Beam Epitaxy (COMBE) Apparatus and Method, filed Sep. 27, 1999, and also incorporated herein by reference.

Layer deposition is preferably by ALL-MBE (atomic layer-by-layer molecular beam epitaxy), a technique developed in the last decade for deposition of single-crystal thin films of cuprate superconductors and other complex oxides. [1, 2, 3] An ALL-MBE system consists of an ultra-high vacuum chamber equipped with a number of thermal effusion sources (Knudsen cells) with computer-controlled shutters. To monitor the atomic fluxes, atomic absorption spectroscopy has been proved the most useful, since this is accurate enough to detect changes of less than one per cent and fast enough to allow real-time feedback control. By using a pure ozone beam, sufficient oxidation can be achieved under high vacuum conditions, which permits in-situ monitoring of the surface structure by RHEED (reflection high-energy electron diffraction) and other surface analytical tools. [8].

Thin films grown by ALL-MBE typically show atomically flat surfaces and, in the case of superlattices and multi-layers, virtually perfect interfaces. Next, surfaces and interfaces can be controlled. For example, the surface layer of an asgrown or cleaved Bi₂Sr₂CaCu₂O₈₊ₓ single crystal is most likely to be a Bi—O layer —layer this is a natural termination plane as well as the easiest cleavage plane. Layer-by-layer growth, however, can be terminated at any desired atomic mono-layer, e.g., at a CuO₂ plane. If one wants to switch to another compound at that point, the starting plane can again be selected at will. This provides great flexibility in tailoring surfaces and interfaces, as long as surface reconstruction can be avoided, and opens new avenues in fabrication of devices such as tri-layer (or “sandwich”) junctions, for example. Traditionally, the barrier layer is inserted between the two naturally terminated layers of the host material (the bottom and the top electrode); here, it is possible to insert a layer of a foreign compound in-between two “inner” planes of a host compound which are not natural termination planes.

Next, layer-by-layer growth makes it easy to deposit a fraction of a monolayer of a given atomic species and then complete the monolayer with another element. In this way, if there is no bulk diffusion, one can select at will the monolayers to be doped. The dopant may be picked to have a different valence, which enables one to modify and control the local charge carrier density. Modulation doping has been accomplished in this manner. [3]

Next, in complex compounds one frequently finds several energetically degenerate or nearly degenerate phases; a familiar example is provided by 2201, 2212, 2223, 2234, etc. phases in the Bi₂Sr₂Caₙ₋₁CuₙO₂ₙ₊₄₊ₓ family. In general, by cooling the melt one obtains a mixture of these phases, for entropy reasons. Layer-by-layer growth, however, enables one to discriminate among such phases, i.e., to selectively grow the desired one only. Unless the temperature is raised, the topological barrier will protect the phase grown, since phase separation would require extensive bulk diffusion. In this way, it has been possible to assemble metastable compounds such as Bi₂Sr₂Caₙ₋₁CuₙO₂ₙ₊₄₊ₓ and BiSr₂Caₙ₋₁CuₙO₂ₙ₊₃₊ₓ with n up to 10; these were the first truly ‘artificial’ high-T_{c} materials.

### B. CMR/FE/HTS Heterostructures

FIG. 3 shows a simple tri-layer oxide heterostructure 10 formed by depositing metal oxide layers on a substrate 12, in accordance with the invention. The structure shown in the figure includes a bottom HTS layer 14, a central FE layer 16, and a top CMR layer 18. Although the device may include all three layers, more typically it includes a heterostructure device having a substrate, the HTS layer, and either the FE layer of the CMR layer formed on the HTS device. The film is patterned into a mesa structure, with four bottom (1, 2, 7, 8) and four top (3, 4, 5, 6) gold electrical contacts, such as bottom electrode 20 and top electrode 22. Where the device includes only the FE layer on the HTS layer, the four top electrical contacts are formed directly on the FE layer.

### Device Functioning

T_{c} of the HTS layer can be determined from a four-point contact resistance R(T) measurement, using contacts I(1,4) and V(2,3). Alternatively, T_{c} can be determined from χ (T) measurement.

The CMR effect, i.e., the difference between R(T, H=0) in zero field, and R(T, H) in a high magnetic field H (several Tesla) can be made from a four-point contact resistance R(T) measurement, using contacts I(5,8) and V(6,7).

FE properties can be determined from a C(V) measurement (e.g., by the Tower-Sawyer technique) using contacts V(1,8). Here, the CMR layer acts as the top electrode and the HTS layer acts as the bottom electrode of the capacitor.

Exemplary metal oxide materials for the layers are:

HTS: La_{1.85}Sr_{0.15}CuO₄, DyBa₂Cu₃O₇, Bi₂Sr₂CaCu₂O₈.

FE: (Ba,Sr)TiO₃, PbTiO₃, (Pb,La)(Zr,Ti)O₃, Bi₃Ti₄O₁₀.

CMR: La_{0.66}Sr_{0.34}MnO₄, La_{0.66}Ca_{0.34}MnO₄, La_{0.66}Ba_{0.34}MnO₄.

All of these compounds are well lattice-matched to one another, allowing for good hetero-epitaxy. Furthermore, they can be grown under similar thermodynamic conditions: Tₛ=680-720° C., and p=1-10×10⁻⁶ Torr of O₃/O₂ mixture. The only exception is PbTiO₃, which requires a lower deposition temperature, typically Tₛ₌550° C. However, once PbTiO₃ is grown at this temperature, and covered with the next (CMR) layer, it may remain stable (i.e., there is no major inter-diffusion between the three layers) even when the temperature is raised to say 680° C.

Preferred layer thickness is 50-100 nm for the bottom (HTS) electrode, 100-200 nm for the FE insulator layer, and 50-100 nm for the top CMR layer.

To simplify the analysis of the CMR measurement, it is preferable to deposit a FE layer that is thick enough to essentially block the current flow through it. This will generally be the case even with a very thin FE layer. For example, for a La_{0.66}Sr_{0.34}MnO₄ strip with the dimensions 30 μm×300 μm×100 nm, the in-plane resistance may be about 100 Ω. In contrast, for a strip of (Ba,Sr)TiO₃ with the same dimensions, the z-axis (out-of-plane) resistance may be over 1 MΩ.

### C. MTJ/HTS Hybrid Device

### C1. Out-of-plane read-out current

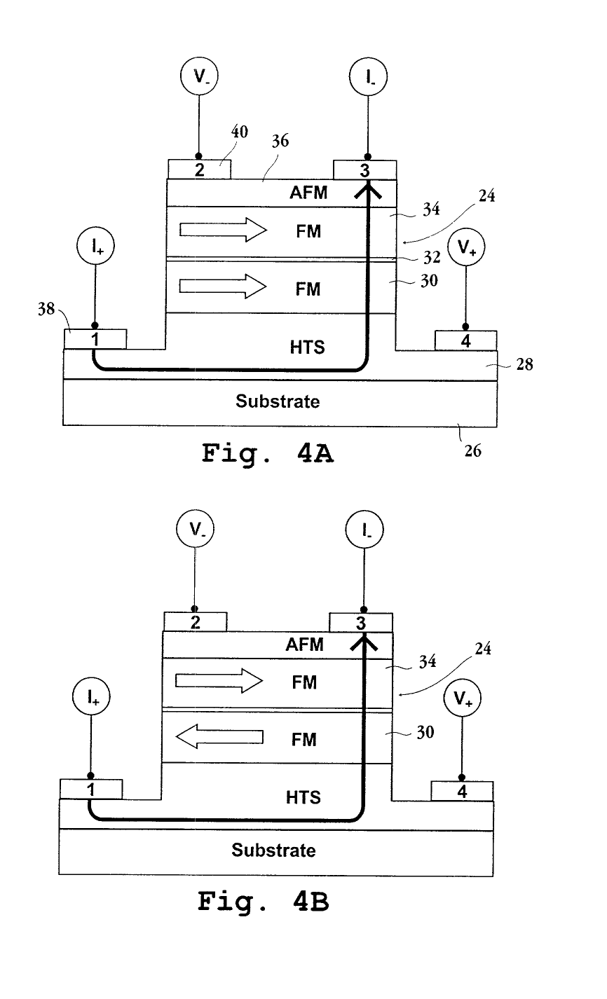

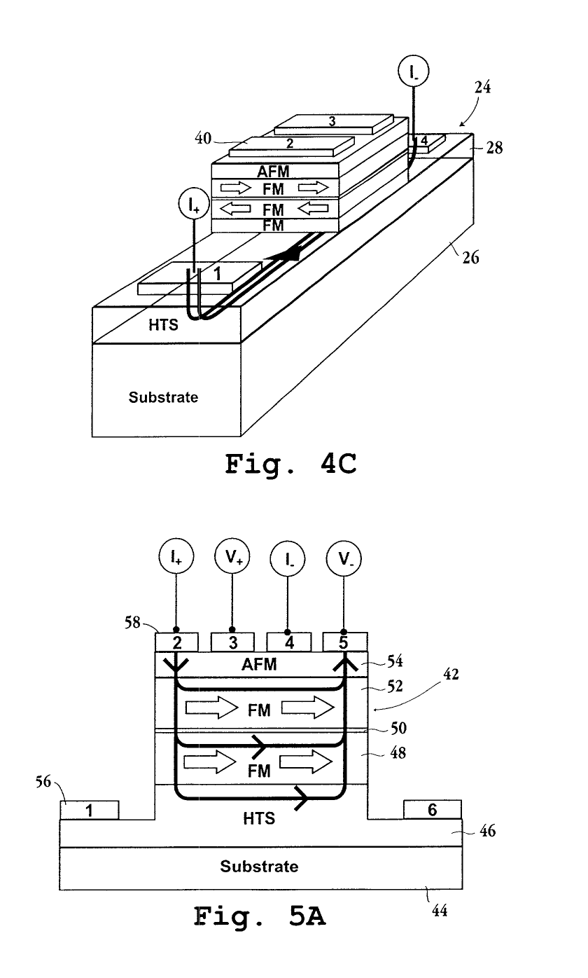

This embodiment of the invention provides a non-volatile, fast magnetic oxide memory device, with superconducting line for writing. In FIG. 4A is shown a five-layer heterostructure device 24 having a suitable substrate 26, and metal oxide layers consisting of an HTS layer 28, a bottom FM electrode layer 30, an ultra-thin insulating barrier 32, a top FM electrode layer 34, and a topmost anti-ferromagnetic (AFM) anchor layer 36. CMR compounds are a natural choice for the electrodes, but any other spin-polarized oxide ferromagnet can be used, as long as epitaxy is good, and interfaces reasonably perfect. The multi-layer film is etched (e.g., by ion milling) into a mesa structure, as shown in FIG. 4A. Also displayed are two gold electrical contacts at the bottom (1, 4), such as contact 38, and two at the top (2, 3), such as contact 40. The contacts make possible four-point contact resistance measurement, with the current flowing in the z-axis direction, i.e., perpendicular to the film surface.

Exemplary metal-oxide layers for the device are:

HTS: DyBa₂Cu₃O₇, La_{1.85}Sr_{0.15}CuO₄, Bi₂Sr₂CaCu₂O₈.

FM: La_{0.66}Sr_{0.34}MnO₄, La_{0.66}Ca_{0.34}MnO₄, La_{0.66}Ba_{0.34}MnO₄.

Insulator SrTiO₃, DyTiO₃, La₂CuO₄, and many others.

Substrate SrTiO₃, LaAlO₃, LaSrAlO₄, and many others.

All of these materials can be deposited, as single crystal thin films, under similar conditions, Tₛ=680-720° C., and p=1-10×10 ⁻⁶ Torr of O₃/O₂ mixture. Instead of manganites that show CMR effect, other oxide ferromagnets can be used as well.

Preferred layer thickness is about 50-100 nm for the bottom (HTS) electrode, 50-100 nm for the bottom FM layer, 1-3 nm for the insulator layer, 50-100 nm for the top FM layer, and 20-50 nm for the topmost AFM anchor layer.

### Device Functioning

For read-out, the connections are I(1,3), V(2,4). If the magnetic moments of the two FM layers are parallel to one another (“open” position of the MTJ), as in FIG. 4A, the read-out voltage is small. If they are anti-parallel (MTJ is “closed”), as in FIG. 4B, the read-out voltage is large. Thus the magnitude of the voltage V(2,4) indicates the magnetic moment orientation of the free electrode (here, the bottom one). This provides for non-destructive electronic read-out of the memory state.

For writing, the connections I(1,4) are used to run a dc (super)current, as shown in FIG. 4C. This current can be considerable. For example, if the HTS strip is 0.2 μm thick and 5 μm wide, it has a cross section of 10⁻⁸ cm²; if j_{c}=10⁷ A/cm², one gets I=100 mA. This current can generate a magnetic field of ca. 100 Gauss in the neighboring (bottom) FM electrode, enough to orient its magnetization vector along the field vector. On the other hand, the magnetization of the top electrode is anchored in a fixed orientation, by interaction with a strong AFM over-layer.

In this way, one can use the current in the HTS line to control the state of the MTJ, i.e., for direct writing in the MRAM circuit.

### C2. In-plane Read-out Current

This is an alternative embodiment of the device described in C1, and provides a non-volatile, fast magnetic oxide memory (spin-valve) device, with superconducting line for writing.

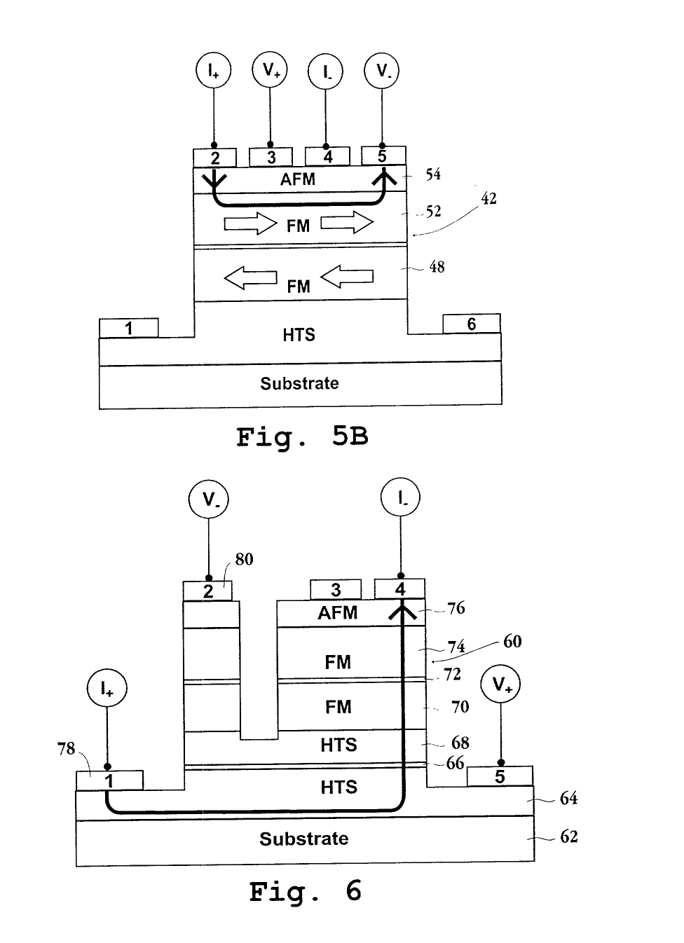

In particular, the multi-layer structure of the films is the same as in the previous example. The difference is that here is that there are four electrical contacts (2,3,4,5) on the top, as shown in FIG. 5A. The heterostructure structure, indicated at 42 in FIGS. 5A and 5B, includes a substrate 44, a lower HTS layer 46, and three middle layers—top and the bottom FM electrodes 48, 52, separated by an insulating barrier layer 50--, and an upper AFM layer 54. HTS electrical contacts (1, 6), such as contact 56, and upper electrical contacts (2,3,4,5), such as contact 58, are as shown.

The heterostructure device has two positions or states: “open” when the two magnetic layers have parallel polarization (FIG. 5A), and “closed” when they are anti-parallel (FIG. 5B). It is assumed that in the “closed” position of the MTJ, the insulator barrier resistance R_{cl} (for the current flowing out-of-plane, i.e., along the z axis) is larger than the in-plane, x−(or y−) axis resistance of the top FM electrode, R_{T}, while in the open “position”, the opposite is true, Rₒₚ<R_{T}. It is also assumed that the resistance R_{B} of the bottom metallic electrode, comprised of the lower FM layer and the HTS under-layer, is also smaller than R_{T}. In this case, there will be a substantial dependence of the in-plane current, for constant voltage (or voltage, for constant current) across the contacts on the state of the spin valve.

For example, assume R_{T}=100 Ω, Rₒₚ=30 Ω, R_{cl}=300 Ω, and R_{B}=10 Ω. In this case, if the MTJ is closed, one has the total resistance R_{eq}≃75 Ω while if it is open, R_{eq}≃40 Ω, i.e., almost a factor of two smaller. Therefore, one can expect a very large magneto-resistance effect, even at low magnetic fields (e.g., 100 Gauss). Notice that all that is needed is that the field is strong enough to switch the polarization of the bottom ferromagnetic electrode with respect to that of the top electrode (or vice versa).

For the above effect, the bottom HTS layer is indeed not necessary. The point here is that it does not hinder the operation of the spin valve, for the in-plane transport measurement. On the other hand, it allows for writing, by changing the orientation of magnetization of the bottom FM electrode, as discussed below.

### Device Functioning

For read-out, the connections are: I(2,5), V(3,4). If the magnetic moments of the two CMR layers are parallel to one another (“open” position of the MTJ), as in FIG. 5a, the read-out voltage is small. If they are anti-parallel (MTJ is “closed”), as in FIG. 5b, the read-out voltage is large. This allows for an electronic read-out of the magnetic moment orientation of the free electrode (here, the bottom one), i.e., of the state of the memory element.

For writing, the connections I(1,6) are used to run a dc (super)current, which generates a magnetic field that flips the orientation of magnetization of the bottom FM electrode at will.

### D. MTJ/JJ Hybrid Device

This embodiment of the device, illustrated in FIG. 6, provides a hybrid device 60 acting as an MTJ and/or as a JJ. The magnetic memory has a twofold readout, one low-voltage and another high-voltage. The JJ is “erasable”.

The multi-layer structure of the films is similar as in the previous example, except as follows: The single HTS layer is replaced by a three-layer JJ; that is, the device is a seven-layer heterostructure having a two HTS layers 66, 70 sandwiching an insulating layer 66, upper and lower FM layers 70, 74, sandwiching an insulating barrier layer 72, and a topmost AFM layer 76. The device has five contacts, two at the bottom (1,5), such as contact 78, and three on the top (2,3,4), such as contact 80), as shown. Finally, there is there is an extra cut, generated by ion milling, between the electrodes 3 and 4, going all the way to the top superconducting layer. This added barrier can be either metallic, in which case one has a SNS junction, or insulating, rendering an SIS junction.

Materials choice:

HTS: La_{1.85}Sr_{0.15}CuO₄, DyBa₂Cu₃O₇, Bi₂Sr₂CaCu₂O₈.

FM: La_{0.66}Sr_{0.34}MnO₄, La_{0.66}Ca_{0.34}MnO₄, La_{0.66}Ba_{0.34}MnO₄, and other oxide ferromagnets.

lnsulator::SrTiO₃, DyTiO₃, La₂CuO₄, and many others.

Substrate: SrTiO₃, LaAlO₃, LaSrAlO₄, and many others.

### Device Functioning

For read-out, the connections are: I(1,4), V(2,5). For T<T_{c}, the two HTS layers are superconducting. In a four-point contact measurement, which eliminates the contact resistance of the voltage leads, what is measured in this configuration is the voltage drop across the barrier of the JJ.

Although the heterostructure device of the invention has been described with respect to particular embodiments, it will be appreciated that various other embodiments and modifications within the scope of the claims are contemplated.

It is claimed:

1. A hybrid oxide heterostructure device comprising
a substrate
a high-temperature superconducting (HTS) structure having one or more HTS metal oxide layers, and electrical contacts formed on one or more HTS layers, and
a multi-layer magnetic memory-storage structure having one or more metal oxide magnetic layers formed monolithically below, on or between the HTS device, on the substrate, and having electrical contacts formed on one or more of the magnetic layers,
wherein application of current or voltage to the HTS structure, under conditions effective to establish a superconducting current in the HTS structure, is effective to alter read or write characteristics of the memory-storage structure.

2. The device of claim 1, wherein said HTS and magnetic layers are formed successively by atomic layer-by-layer molecular beam epitaxy.

3. The device of claim 1, wherein said HTS structure has a single HTS layer, the memory-storage structure includes a metal oxide ferroelectric (FE) memory layer formed on the HTS layer, the HTS-structure electrical contacts are formed on opposite sides of the HTS layer, and the memory-storage-structure electrical contacts are formed on the FE layer.

4. The device of claim 3, wherein the HTS layer is composed of a metal oxide selected from the group consisting of La_{1.85}Sr_{0.15}CuO₄, DyBa₂Cu₃O₇, and Bi₂Sr₂CaCu₂O₈; and the FE layer is composed of a metal oxide selected from the group consisting of (Ba,Sr)TiO₃, PbTiO₃, (Pb,La)(Zr,Ti)O₃, and Bi₃Ti₄O₁₀.

5. The device of claim 1, wherein said HTS structure has a single HTS layer, the memory-storage structure includes a metal oxide colossal magnetic resistance (CMR) layer formed on the HTS layer, the HTS-structure electrical contacts are formed on opposite sides of the HTS layer, and the magnetic-storage-structure electrical contacts are formed on the CMR layer.

6. The device of claim 5, wherein the HTS layer is composed of a metal oxide selected from the group consisting of La_{1.85}Sr_{0.15}CuO₄, DyBa₂Cu₃O₇, and Bi₂Sr₂CaCu₂O₈; and the CMR layer is composed of a metal oxide selected from the group consisting of La_{0.66}Sr_{0.34}MnO₄, La_{0.66}Ca_{0.34}MnO₄, and La_{0.66}Ba_{0.34}MnO₄.

7. The device of claim 1, wherein said HTS structure has a single HTS layer, the memory-storage structure includes a magnetic tunnel junction (MTJ) structure composed of a first ferromagnetic (FM) formed on the HTS layer, an insulating layer formed on the first FM layer, a second FM layer formed on the insulating layer, and a anti-ferromagnetic (AFM) layer formed on the second FM layer, the HTS-structure electrical contacts are formed on opposite sides of the HTS layer, and the magnetic/storage-structure electrical contacts are formed on the AFM layer.

8. The device of claim 7, wherein the HTS layer is composed of a metal oxide selected from the group consisting of La_{1.85}Sr_{0.15}CuO₄, DyBa₂Cu₃O₇, and Bi₂Sr₂CaCu₂O₈; the FM layer is composed of a metal oxide selected from the group consisting of La_{0.66}Sr_{0.34}MnO₄, La_{0.66}Ca_{0.34}MnO₄, and La_{0.66}Ba_{0.34}MnO₄..

9. The device of claim 7, wherein the electrical contacts in the magnetic/storage are arranged for in-plane read-out current.

10. The device of claim 7, wherein the electrical contacts in the magnetic/storage are arranged for out-of-plane read-out current.

11. The device of claim 1, wherein said HTS structure is a Josephson Junction (JJ) having a first HTS layer formed on the substrate, an insulating-barrier layer formed on the first HTS layer, and a second HTS layer formed on the insulating-barrier layer, the memory-storage structure includes a magnetic tunnel junction (MTJ) structure composed of a first ferromagnetic (FM) formed on the second HTS layer, an insulating barrier layer formed on the first FM layer, a second FM layer formed on the barrier layer, and a anti-ferromagnetic (AFM) layer formed on the second FM layer, the HTS-structure electrical contacts are formed on opposite sides of the HTS layer, and the magnetic-storage-structure electrical contacts are formed on the AFM layer.

12. The device of claim 11, wherein the HTS layer is composed of a metal oxide selected from the group consisting of La_{1.85}Sr_{0.15}CuO₄, DyBa₂Cu₃O₇, and Bi₂Sr₂CaCu₂O₈; and the FM layer is composed of a metal oxide selected from the group consisting of La_{0.66}Sr_{0.34}MnO₄, La_{0.66}Ca_{0.34}MnO₄, and La_{0.66}Ba_{0.34}MnO₄.
